(19) United States
(12) Patent Application Publication
(10) Pub. No.: US 2026/0047487 A1
(43) Pub. Date: Feb. 12, 2026

(54) SEMICONDUCTOR PACKAGE AND MEMORY SYSTEM

(71) Applicant: SAMSUNG ELECTRONICS CO., LTD., Suwon-si (KR)

(72) Inventors: Daehyun KWON, Suwon-si (KR); Joonyoung PARK, San Jose, CA (US); Hyejung KWON, Suwon-si (KR); Changsik YOO, Suwon-si (KR); Jeongdon IHM, Suwon-si (KR); Wonho CHOI, Suwon-si (KR)

(73) Assignee: SAMSUNG ELECTRONICS CO., LTD., Suwon-si (KR)

(21) Appl. No.: 19/037,643

(22) Filed: Jan. 27, 2025

Related U.S. Application Data
(60) Provisional application No. 63/679,960, filed on Aug. 6, 2024.

(51) Int. Cl. H01L 25/18; H01L 23/00; H01L 23/538; H01L 25/065; H10B 10/00; H10B 12/00; H10B 61/00; H10B 63/10; H10B 80/00

(52) U.S. Cl. CPC H01L 25/18; H01L 23/5389; H01L 25/0652; H10B 10/18; H10B 12/50; H10B 61/00; H10B 63/10; H10B 80/00; H01L 24/48; H01L 2224/48225; H01L 2924/1436

(57) ABSTRACT

A semiconductor package includes a first device including a plurality of memory chips, and a second device configured to provide a signal received from the first device through a first channel, to an external device through a second channel, and provide a signal received from the external device through the second channel to the first device through the first channel, wherein the second device includes an equalization circuit configured to equalize a signal received by the second device, a termination circuit configured to control an electrical connection state of termination resistors, and a bypass circuit configured to control a bypass switch based on noise of a signal received through the first channel and the second channel.

### CROSS-REFERENCE TO RELATED APPLICATION

This application is based on and claims priority under 35 U.S.C. § 119 to U.S. Provisional Application No. 63/679,960, filed on Aug. 6, 2024, in the United States Patent and Trademark Office, the disclosure of which is incorporated by reference herein in its entirety.

### BACKGROUND

The embodiments relate to a semiconductor package and a memory system, and more particularly, to a semiconductor package and a memory system that include an equalization circuit, a termination circuit, and a bypass circuit.

Recently, with the development of data technology, a huge amount of data signals are transmitted and received between devices, and accordingly, interfacing technology is required to facilitate data transmission and reception. However, a design that focuses only on the data transmission speed, such as widening the bandwidth between devices transmitting and receiving data, results in deterioration in the quality of signals. For example, devices may be connected through a channel configured to transmit a data signal, but due to various factors, such as skin effect and dielectric loss, the data signal transmitted through the channel may include noise, such as intersymbol interference (ISI), and thus, the quality of the data signal transmitted at high speed may be deteriorated.

### SUMMARY

According to an aspect of the disclosure a semiconductor package includes: a substrate; a first device including a plurality of memory chips; and a second device configured to (i) provide a first signal received from the first device through a first channel to an external device through a second channel, and (ii) provide a second signal received from the external device through the second channel to the first device through the first channel, wherein the first channel connects the first device to the second device, and the second channel connects the external device to the second device, wherein the second device includes: an equalization circuit connected to the first channel and the second channel, the equalization circuit configured to equalize the first signal received from the first device and the second signal received from the external device; a termination circuit configured to control an electrical connection state of a plurality of termination resistor circuits based on a termination request received from the first device and the external device; and a bypass circuit comprising a bypass switch connected in parallel with the equalization circuit, the bypass circuit configured to control the bypass switch based on noise of the first signal received through the first channel and noise of the second signal received through the second channel.

According to an aspect of the disclosure, a semiconductor package includes: a first package comprising (i) a first substrate, and (ii) a first device comprising a plurality of memory chips, connected to the first substrate; and a second package comprising (i) a second substrate connected to the first substrate, and (ii) a second device configured to (a) provide a first signal received from the first device through a first channel to an external device through a second channel, and to (b) provide a second signal received from the external device through the second channel to the first device through the first channel, the second device being connected to the second substrate, wherein the first channel connects the first device to the second device, and the second channel connects the external device to the second device, wherein the second device includes: an equalization circuit connected to the first channel and the second channel, the equalization circuit configured to equalize the first signal received from the first device and the second signal received from the external device; a termination circuit configured to control an electrical connection state of a plurality of termination resistor circuits based on a termination request received from the first device and the external device; and a bypass circuit comprising a bypass switch connected in parallel with the equalization circuit, the bypass circuit configured to control the bypass switch based on noise of the first signal received through the first channel and noise of the second signal received through the second channel.

According to an aspect of the disclosure, a memory system includes: an input/output signal processing device connected to a first channel and a second channel; a memory device including a plurality of memory chips and connected to the input/output signal processing device through the first channel; and a memory controller connected to the input/output signal processing device through the second channel, wherein the input/output signal processing device is configured to (i) provide a first signal received from the memory device through the first channel to the memory controller through the second channel, and (ii) provide a second signal received from the memory controller through the second channel to the memory device through the first channel, and wherein the input/output signal processing device includes: an equalization circuit configured to equalize the first signal received from the memory device and the second signal received from the memory controller; a termination circuit configured to control an electrical connection state of a plurality of termination resistor circuits based on a termination request received from the memory device and the memory controller; and a bypass circuit configured to control a bypass switch connected in parallel with the equalization circuit based on noise of the first signal received through the first channel and noise of the second signal received through the second channel.

### BRIEF DESCRIPTION OF DRAWINGS

Embodiments will be more clearly understood from the following detailed description taken in conjunction with the accompanying drawings in which:

FIG. 1 is a block diagram of a memory system according to one or more embodiments;

FIG. 2 is a diagram illustrating a memory system according to one or more embodiments;

FIG. 3 is a diagram illustrating an equalization circuit according to one or more embodiments;

FIGS. 4A to 4D are diagrams illustrating a termination circuit according to one or more embodiments;

FIGS. 5A to 5C are diagrams illustrating a bypass circuit according to one or more embodiments;

FIGS. 6 and 7 are diagrams illustrating a semiconductor package according to one or more embodiments;

FIGS. 8 and 9 are diagrams illustrating a semiconductor package according to one or more embodiments; and

FIG. 10 is a block diagram of a system according to one or more embodiments.

### DETAILED DESCRIPTION OF EMBODIMENTS

With the recent development of data technology, the amount of data transmitted and received between devices has increased. Therefore, a method is required to transmit data between devices at high speed while improving the quality of signals. In addition, a method is required to reduce the amount of power consumed by the devices during this process.

Hereinafter, one or more embodiments will be described in detail with reference to the accompanying drawings. When describing components with reference to the drawings, the same reference numerals are used for the same or corresponding components in the drawings, and duplicate descriptions thereof are omitted.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

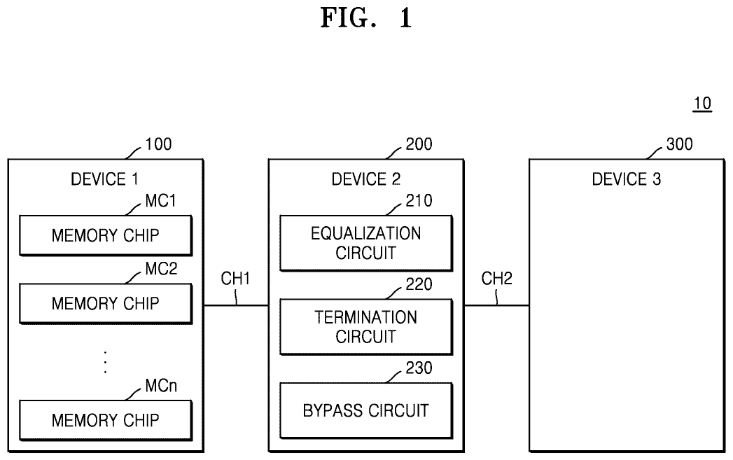

FIG. 1 is a block diagram of a memory system 10 according to one or more embodiments.

Referring to FIG. 1, the memory system 10 may include a first device 100, a second device 200, and a third device 300. As understood by one of ordinary skill in the art, although FIG. 1 illustrates three devices, the embodiments are not limited to this configuration. For example, the embodiments may include any number of devices as well as any number of channels between the devices.

The first device 100 may be implemented as a volatile memory device. The volatile memory device may be implemented as Random Access Memory (RAM), Dynamic RAM (DRAM), or Static RAM (SRAM), but is not limited thereto. For example, the first device 100 may correspond to Double Data Rate Synchronous Dynamic Random Access Memory (DDR SDRAM), Low Power Double Data Rate (LPDDR) SDRAM, Graphics Double Data Rate (GDDR) SDRAM, Rambus Dynamic Random Access Memory (RDRAM), or any other suitable memory structure known to one of ordinary skill in the art.

The first device 100 may be implemented as a non-volatile memory device. For example, the first device 100 may be implemented as a resistive memory, such as Phase change RAM (PRAM), Magnetic RAM (MRAM), or Resistive RAM (RRAM).

The first device 100 may include a plurality of memory chips MC1 to MCn (where n is a natural number greater than or equal to 2).

In one or more embodiments, each of the plurality of memory chips MC1 to MCn may include an input/output circuit that serializes and outputs a signal. In other words, the data output by each of the plurality of memory chips MC1 to MCn may be serialized data.

The second device 200 may provide, to the third device 300, a signal (e.g., first signal) received from the first device 100, and may provide, to the first device 100, a signal (e.g., second signal) received from the third device 300. A first channel CH1 may be connected between the first device 110 and the second device 120 through connectors. A second channel CH2 may also be connected between the second device 200 and the third device 300 through connectors.

In one or more embodiments, the connectors may be implemented as pins, balls, signal lines, or any other suitable hardware components known to one of ordinary skill in the art.

In one or more embodiments, the first device 100 may provide a signal to the second device 200 through the first channel CH1. The third device 300 may provide a signal to the second device 200 through the second channel CH2. In one or more examples, the signal transmitted and received between the first device 100 and the third device 300 via the first channel CH1 and the second channel CH2 may be a single-ended signal. As understood by one of ordinary skill in the art, in single-ended signaling, one wire in a channel may carry a varying voltage, while another wire is connected to a reference voltage (e.g., ground). In one or more examples, the signal transmitted and received between the first device 100 and the third device 300 via the first channel CH1 and the second channel CH2 may be a differential signal. As understood by one of ordinary skill in the art, in differential signaling, a same electrical signal is sent as a differential pair of signals in a respective conductor, where the pair of conductors can be wires in a twisted-pair or ribbon cable. In one or more examples, the signals transmitted in the first channel CH1 and the second channel CH2 may both be single-ended signals or differential signals, or the signals transmitted in one of the channels may be single-ended and the signals transmitted in the other of the channels may be differential. In one or more examples, the channels may be half-duplex or full-duplex. In a half-duplex channel, signals are provided in both directions, but only one direction at a time. In a full-duplex channel, signals may be provided in both directions simultaneously. In one or more examples, the first channel CH1 and the second channel CH2 may be both half-duplex or full duplex, or one of the channels may be half-duplex and the other of the channels may be full-duplex.

The second device 200 may include an equalization circuit 210, a termination circuit 220, and a bypass circuit 230. In some embodiments, the second device 200 may be referred to as an input/output chip, an input/output die, an input/output device, or an input/output signal processing device.

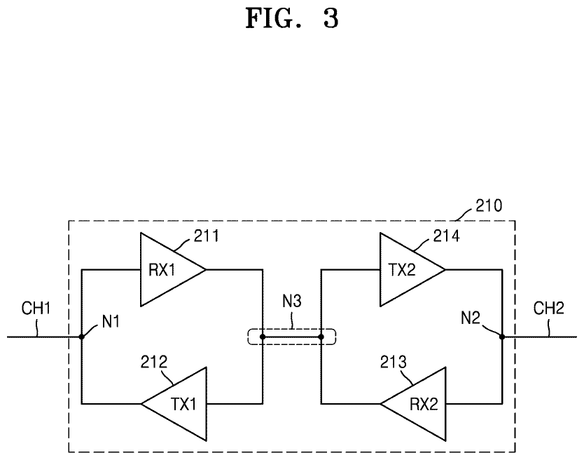

The equalization circuit 210 may equalize a signal received from the first device 100 through the first channel CH1 and provide the equalized signal to the third device 300 through the second channel CH2. In one or more examples, the equalization circuit 210 may equalize a signal received from the third device 300 through the second channel CH2 and provide the equalized signal to the first device 100 through the first channel CH1. A detailed description of the equalization circuit 210 will be described later with reference to FIG. 3.

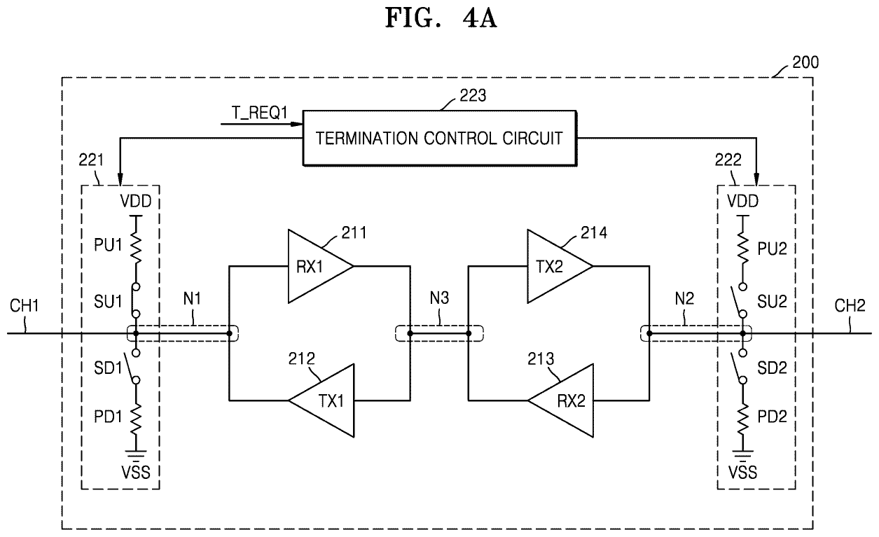

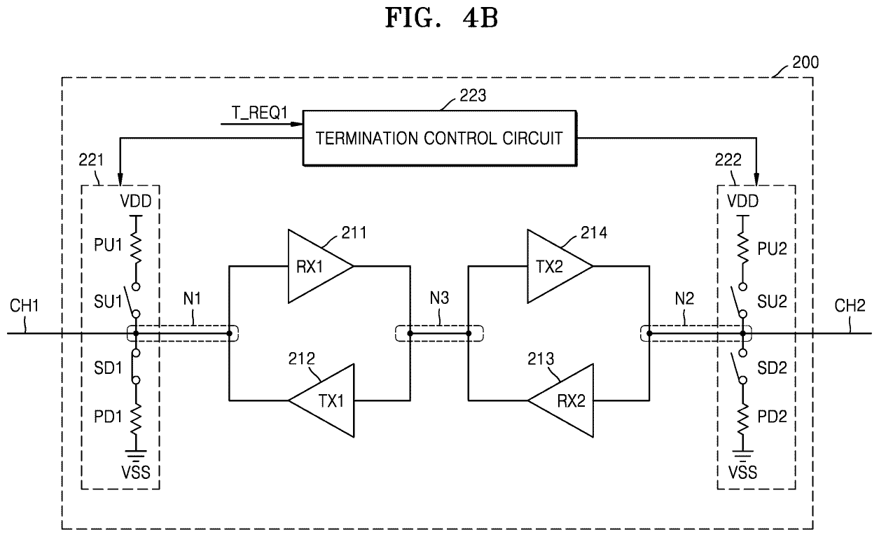

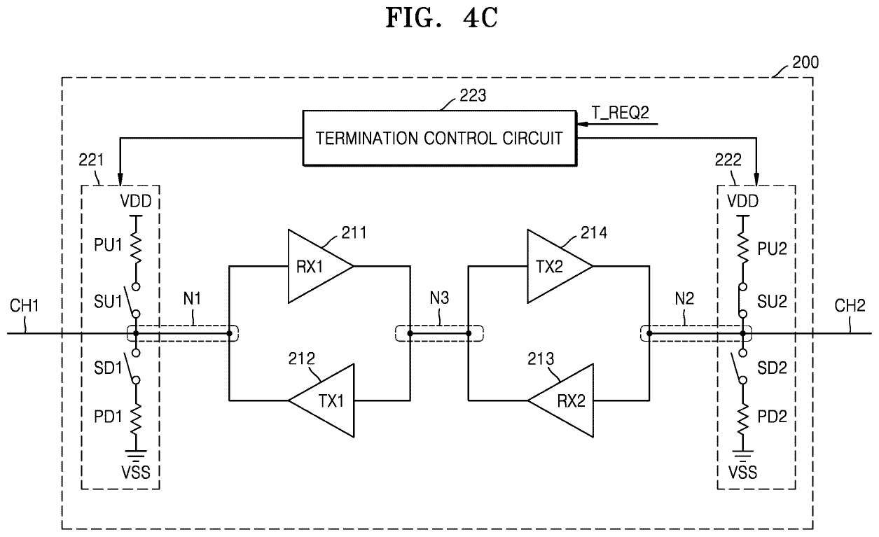

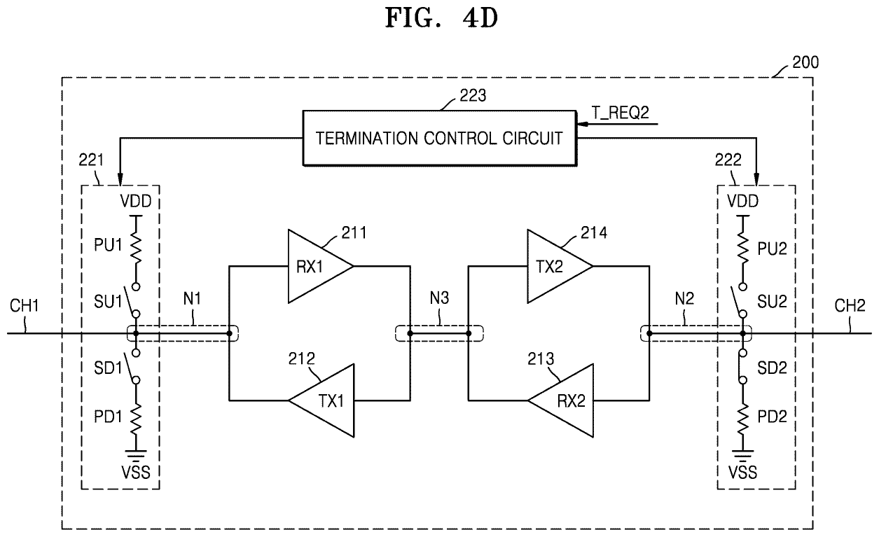

The termination circuit 220 may provide termination resistance to the first channel CH1 and the second channel CH2 by turning on or off termination resistors connected to the first channel CH1 and the second channel CH2 based on a termination request signal received from the first device 100 and the third device 300. A detailed description of the termination circuit 220 will be described later with reference to FIGS. 4A to 4D.

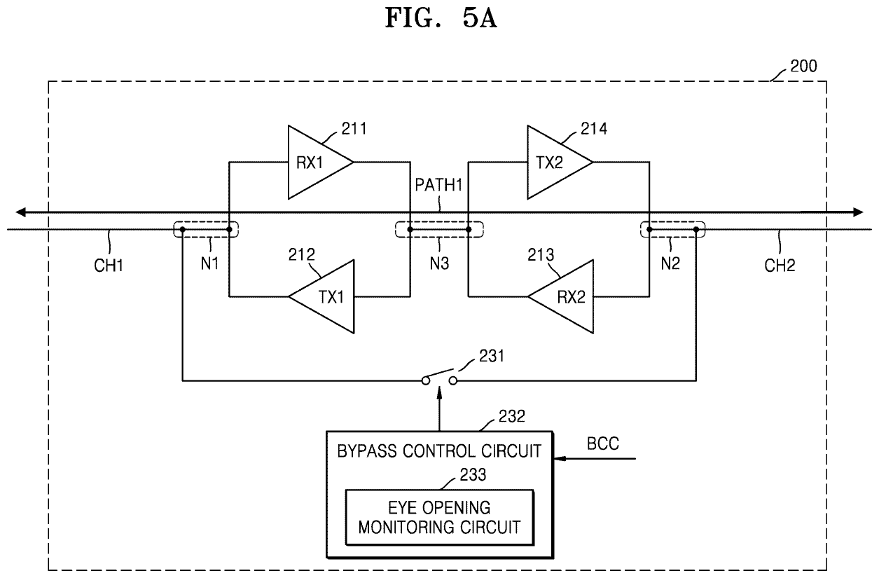

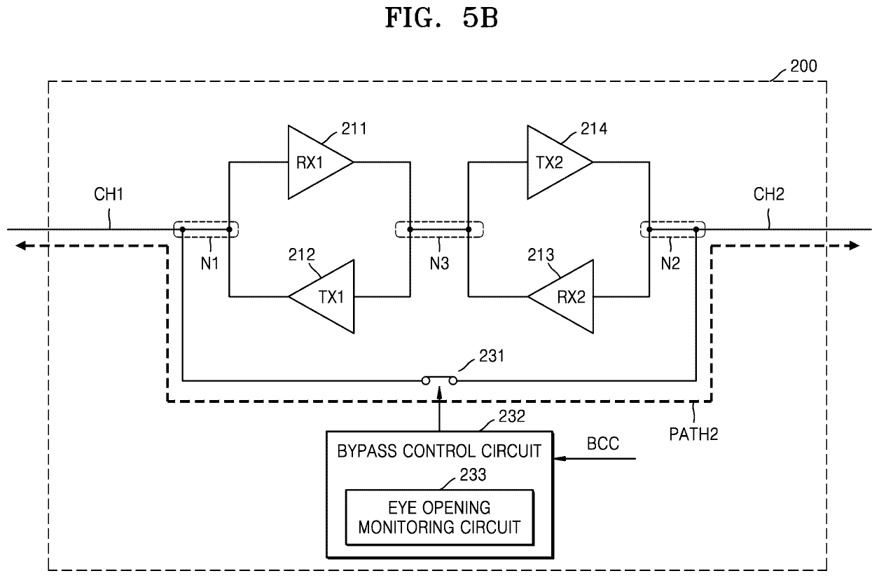

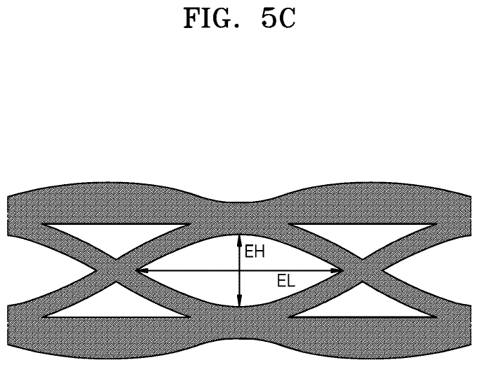

The bypass circuit 230 may activate or deactivate a bypass path based on noise of a signal received from the first channel CH1 and a signal received from the second channel CH2. A detailed description of the bypass circuit 230 will be described later with reference to FIGS. 5A to 5C.

The third device 300 may be implemented as an integrated circuit (IC), a system on chip (SoC), an application processor (AP), a mobile AP, a chipset, or a set of chips. For example, the third device 300 may be a semiconductor device that performs a memory control function, and the third device 300 may also be a configuration included in an AP. The AP may include a memory controller, a RAM, a central processing unit (CPU), a graphics processing unit (GPU), and/or a modem.

According to one or more embodiments, by equalizing a signal in which noise occurs while passing through the first channel CH1 and the second channel CH2 through the equalization circuit 210 of the second device 200, the quality of a signal transmitted and received between the first device 100 and the third device 300 may be improved.

In addition, according to one or more embodiments, by providing a termination resistance to the first channel CH1 and the second channel CH2 through the termination circuit 220 of the second device 200, a voltage required by the first device 100 and the third device 300 for transmitting and receiving a signal may be adjusted, and accordingly, the efficiency of power required for transmitting and receiving a signal between the first device 100 and the third device 300 may be improved.

In addition, according to one or more embodiments, by activating the bypass path according to the degree of noise indicated by a signal received by the second device 200 through the bypass circuit 230 of the second device 200, the power consumption required for signal transmission may be reduced when an equalization operation for the signal is unnecessary.

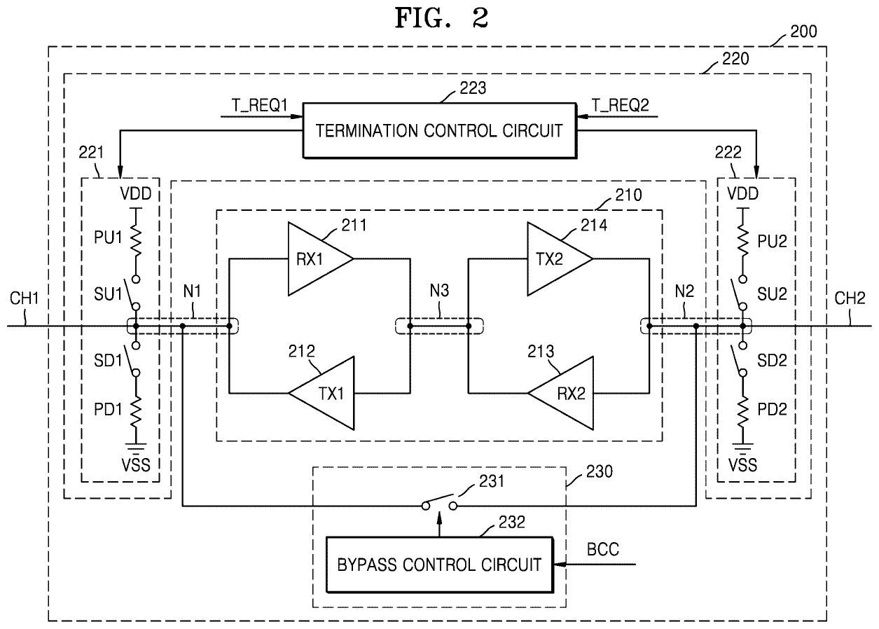

FIG. 2 is a diagram illustrating a memory system according to one or more embodiments. Specifically, FIG. 2 is a diagram showing the memory system 10 of FIG. 1 in more detail. FIG. 2 may be described with reference to FIG. 1, and duplicate descriptions thereof are omitted.

Referring to FIG. 2, the equalization circuit 210 may include a first receiver 211, a first transmitter 212, a second receiver 213, and a second transmitter 214.

The output terminal of the first receiver 211 may be connected to a third node N3, and the input terminal of the first receiver 211 may be connected to a first node N1. The input terminal of the first transmitter 212 may be connected to the third node N3, and the output terminal of the first transmitter 212 may be connected to the first node N1. The output terminal of the second receiver 213 may be connected to the third node N3, and the input terminal of the second receiver 213 may be connected to a second node N2. The input terminal of the second transmitter 214 may be connected to the third node N3, and the output terminal of the second transmitter 214 may be connected to the second node N2.

The termination circuit 220 may include a first termination resistor circuit 221, a second termination resistor circuit 222, and a termination control circuit 223.

The first termination resistor circuit 221 may include a first pull-up resistor PU1, a first pull-up switch SU1, a first pull-down resistor PD1, and a first pull-down switch SD1.

A power supply voltage VDD may be applied to one end of the first pull-up resistor PU1, and the other end of the first pull-up resistor PU1 may be connected to one end of the first pull-up switch SU1. The other end of the first pull-up switch SU1 may be connected to the first node N1. A power supply voltage VSS may be applied to one end of the first pull-down resistor PD1, and the other end of the first pull-down resistor PD1 may be connected to one end of the first pull-down switch SD1. The other end of the first pull-down switch SD1 may be connected to the first node N1. As understood by one of ordinary skill in the art, the pull-up resistor PU1 pulls a voltage to a logic “high” level when no signal is driving the input (e.g., SU1 is open), and the pull-down resistor PD1 pulls a voltage to a logic “low” level when no signal is driving the input (e.g., SD1 is open).

The second termination resistor circuit 222 may include a second pull-up resistor PU2, a second pull-up switch SU2, a second pull-down resistor PD2, and a second pull-down switch SD2.

The power supply voltage VDD may be applied to one end of the second pull-up resistor PU2, and the other end of the second pull-up resistor PU2 may be connected to one end of the second pull-up switch SU2. The other end of the second pull-up switch SU2 may be connected to the second node N2. The power supply voltage VSS may be applied to one end of the second pull-down resistor PD2, and the other end of the second pull-down resistor PD2 may be connected to one end of the second pull-down switch SD2. The other end of the second pull-down switch SD2 may be connected to the second node N2. As understood by one of ordinary skill in the art, the pull-up resistor PU2 pulls a voltage to a logic “high” level when no signal is driving the input (e.g., SU2 is open), and the pull-down resistor PD2 pulls a voltage to a logic “low” level when no signal is driving the input (e.g., SD2 is open).

In one or more embodiments, the first termination resistor circuit 221 and the second termination resistor circuit 222 may be implemented using a plurality of transistors.

In one or more examples, the termination control circuit 223 turning on/off a pull-up resistor and a pull-down resistor may refer turning on/off a switch connected in series with the pull-up resistor and the pull-down resistor. For example, when the termination control circuit 223 turns on the first pull-up resistor PU1, it may mean that the first pull-up switch SU1 connected in series with the first pull-up resistor PU1 is turned on, thereby electrically connecting the first pull-up resistor PU1 to the first node N1. Also, for example, when the termination control circuit 223 turns off the first pull-up resistor PU1, it may mean that the first pull-up switch SU1 connected in series with the first pull-up resistor PU1 is turned off, thereby preventing the first pull-up resistor PU1 from being electrically connected to the first node N1.

The termination control circuit 223 may control the electrical connection state of resistors included in the first termination resistor circuit 221 based on a first termination request signal T_REQ1 received from the first device 100. In one or more examples, the termination control circuit 223 may change the electrical connection state of resistors included in the second termination resistor circuit 222 based on a second termination request signal T_REQ2 received from the third device 300. In one or more embodiments, in which the termination control circuit 223 changes the electrical connection state of the resistors included in the first termination resistor circuit 221 and the second termination resistor circuit 222, will be described later with reference to FIGS. 4A to 4D.

The bypass circuit 230 may include a bypass switch 231 and a bypass control circuit 232.

The bypass switch 231 may be connected in parallel with the equalization circuit 210. For example, one end of the bypass switch 231 may be connected to the first node N1, and the other end of the bypass switch 231 may be connected to the second node N2. In other words, one end of the bypass switch 231 may be connected to the first channel CH1, and the other end of the bypass switch 231 may be connected to the second channel CH2.

The bypass control circuit 232 may control the bypass switch 231 based on noise of a signal received from the first channel CH1 and a signal received from the second channel CH2. In one or more examples, the bypass control circuit 232 may control the bypass switch 231 based on a bypass control signal BCC. The bypass control signal BCC may be a signal generated by an external device (e.g., the third device 300). Example embodiments, in which the electrical connection state of the bypass switch 231 is changed according to the control of the bypass control circuit 232, will be described later with reference to FIGS. 5A to 5C.

FIG. 3 is a diagram illustrating an equalization circuit according to one or more embodiments. FIG. 3 may be described with reference to FIGS. 1 and 2, and duplicate descriptions thereof may be omitted.

Referring to FIG. 3, a signal transmitted and received between the first device 100 and the third device 300 may generate noise while passing through the first channel CH1 and the second channel CH2. The equalization circuit 210 may improve the quality of the signal by performing an equalization operation on the signal transmitted and received between the first device 100 and the third device 300. The equalization circuit 210 may equalize a signal received from the first device 100 through the first channel CH1 and provide the equalized signal to the third device 300 through the second channel CH2. In one or more examples, the equalization circuit 210 may equalize a signal received from the third device 300 through the second channel CH2 and provide the equalized signal to the first device 100 through the first channel CH1.

The signal provided from the first device 100 through the first channel CH1 may be provided to the third device 300 through the second channel CH2 via the first receiver 211 and the second transmitter 214. The signal provided from the third device 300 through the second channel CH2 may be provided to the first device 100 through the first channel CH1 via the second receiver 213 and the first transmitter 212.

In one or more embodiments, the first receiver 211 may equalize a signal received from the first device 100 through the first channel CH1 and provide the equalized signal to the second transmitter 214. The second transmitter 214 may equalize a signal received from the first receiver 211 and provide the equalized signal to the third device 300 through the second channel CH2.

In one or more embodiments, the second receiver 213 may equalize a signal received from the third device 300 through the second channel CH2 and provide the equalized signal to the first transmitter 212. The first transmitter 212 may equalize a signal received from the second receiver 213 and provide the equalized signal to the first device 100 through the first channel CH1.

In one or more embodiments, the first receiver 211 and the second receiver 213 may each include at least one of a decision feedback equalizer (DFE) and a continuous time linear equalizer (CTLE). The equalization operation performed by the first receiver 211 and the second receiver 213 may include at least one of a decision feedback equalization operation or a continuous time linear equalization operation. In one or more examples, a decision feedback equalization operation may refer to a technique used to combat signal distortion caused by inter-symbol interference (ISI) in high-speed data transmission, where a circuit that receives a signal makes decisions about previously received symbols and feeds that information back to help correct the current symbol being received, thereby improving signal quality by canceling out the interference from past symbols. In one or more examples, a continuous time linear equalization process may refer to a technique in which a circuit actively compensates for signal degradation caused by transmission line losses by boosting high-frequency components of a signal, thereby “equalizing” the frequency response to improve signal quality, particularly in high-speed data transmission applications like PCIe or serial interfaces. The circuit performing the continuous time linear equalization process may function as a continuous-time linear filter.

In one or more embodiments, the first transmitter 212 and the second transmitter 214 may each include a feed forward equalizer (FFE). The equalization operation performed by the first transmitter 212 and the second transmitter 214 may include a feed forward equalization operation. In one or more examples, a feed forward equalization process may refer to a technique implemented within a transmitter circuit to pre-distort the signal, effectively compensating for the signal degradation that occurs during transmission through a channel by boosting specific frequency components, thereby reducing inter-symbol interference (ISI) and improving signal quality at the receiver end.

In one or more embodiments, the equalization circuit 210 may further include a circuit that pre-emphasizes or de-emphasizes a signal.

FIGS. 4A to 4D are diagrams illustrating a termination circuit according to one or more embodiments. FIGS. 4A to 4D may be described with reference to FIGS. 1 and 2, and duplicate descriptions thereof may be omitted.

Referring to FIGS. 4A to 4D, a voltage range used by the first device 100 to transmit and receive a signal through the first channel CH1 may different from a voltage range used by the third device 300 to transmit and receive a signal through the second channel CH2.

The termination control circuit 223 may turn on or turn off at least one of the resistors of the first termination resistor circuit 221 based on the first termination request signal T_REQ1 received from the first device 100.

The termination control circuit 223 may turn on or turn off at least one of the resistors of the second termination resistor circuit 222 based on the second termination request signal T_REQ2 received from the third device 300.

Referring to FIG. 4A, the first device 100 may request the termination control circuit 223 to turn on the first pull-up resistor PU1 and turn off the first pull-down resistor PD1 by transmitting the first termination request signal T_REQ1 to the termination control circuit 223. For example, the first termination request signal T_REQ1 may include information requesting to turn on the first pull-up resistor PU1 and turn off the first pull-down resistor PD1. The termination control circuit 223 may turn on the first pull-up resistor PU1 and turn off the first pull-down resistor PD1 based on the first termination request signal T_REQ1.

In one or more embodiments, a voltage range used when the first device 100 transmits and receives a signal through the first channel CH1 may be from a first voltage (e.g., the power supply voltage VDD) to a second voltage (e.g., a voltage corresponding to half of the power supply voltage VDD).

Referring to FIG. 4B, the first device 100 may request the termination control circuit 223 to turn off the first pull-up resistor PU1 and turn on the first pull-down resistor PD1 by transmitting the first termination request signal T_REQ1 to the termination control circuit 223. For example, the first termination request signal T_REQ1 may include information requesting to turn off the first pull-up resistor PU1 and turn on the first pull-down resistor PD1. The termination control circuit 223 may turn off the first pull-up resistor PU1 and turn on the first pull-down resistor PD1 based on the first termination request signal T_REQ1.

In one or more embodiments, a voltage range used when the first device 100 transmits and receives a signal through the first channel CH1 may be from the second voltage to a third voltage (e.g., the power supply voltage VSS).

Referring to FIG. 4C, the third device 300 may request the termination control circuit 223 to turn on the second pull-up resistor PU2 and turn off the second pull-down resistor PD2 by transmitting the second termination request signal T_REQ2 to the termination control circuit 223. For example, the second termination request signal T_REQ2 may include information requesting to turn on the second pull-up resistor PU2 and turn off the second pull-down resistor PD2. The termination control circuit 223 may turn on the second pull-up resistor PU2 and turn off the second pull-down resistor PD2 based on the second termination request signal T_REQ2.

In one or more embodiments, a voltage range used when the third device 300 transmits and receives a signal through the second channel CH2 may be from the first voltage to the second voltage.

Referring to FIG. 4D, the third device 300 may request the termination control circuit 223 to turn off the second pull-up resistor PU2 and turn on the second pull-down resistor PD2 by transmitting the second termination request signal T_REQ2 to the termination control circuit 223. For example, the second termination request signal T_REQ2 may include information requesting to turn off the second pull-up resistor PU2 and turn on the second pull-down resistor PD2. The termination control circuit 223 may turn off the second pull-up resistor PU2 and turn on the second pull-down resistor PD2 based on the second termination request signal T_REQ2.

In one or more embodiments, a voltage range used when the third device 300 transmits and receives a signal through the second channel CH2 may be from the second voltage to the third voltage.

FIGS. 5A to 5C are diagrams illustrating a bypass circuit according to one or more embodiments. FIGS. 5A to 5C may be described with reference to FIGS. 1 and 2, and duplicate descriptions thereof may be omitted.

Referring to FIGS. 5A and 5B, the bypass control circuit 232 may monitor noise of a signal transmitted to the second device 200 through the first channel CH1 and a signal transmitted to the second device 200 through the second channel CH2. The bypass control circuit 232 may change the electrical connection state of the bypass switch 231 based on a result of comparing a noise monitoring result value indicating a result of monitoring noise of the signal with a bypass reference value. The bypass reference value may be a value previously input to the bypass control circuit 232. However, as understood by one of ordinary skill in the art, the embodiments are not limited to this configuration. For example, the bypass reference value may be dynamically determined in real-time by the bypass control circuit based on one or more operation conditions of a semiconductor device.

In one or more embodiments, the bypass control circuit 232 may turn on the bypass switch 231 when at least one of the state of the first channel CH1 and the state of the second channel CH2 is good. In the present specification, the state of the channel being good may mean that the noise monitoring result value corresponding to a signal provided to the second device 200 through a corresponding channel is less than the bypass reference value. For example, the bypass control circuit 232 may compare a first noise monitoring result value, which is a noise monitoring result corresponding to a signal provided to the second device 200 through the first channel CH1, with a first bypass reference value. For example, when the first noise monitoring result value is less than the first bypass reference value, the state of the first channel CH1 may be good. Also, for example, the bypass control circuit 232 may compare a second noise monitoring result value, which is a noise monitoring result corresponding to a signal provided to the second device 200 through the second channel CH2, with a second bypass reference value. For example, when the second noise monitoring result value is less than the second bypass reference value, the state of the second channel CH2 may be good. In some embodiments, the first bypass reference value and the second bypass reference value may be the same or different.

In one or more embodiments, the bypass control circuit 232 may include an Eye Opening Monitoring (EOM) circuit 233. The bypass control circuit 232 may monitor, by using the EOM circuit 233, noise of a signal transmitted to the second device 200 through the first channel CH1 and a signal transmitted to the second device 200 through the second channel CH2.

In one or more embodiments, the bypass control circuit 232 may change the electrical connection state of the bypass switch 231 based on a bypass control signal BCC provided from the third device 300, regardless of the noise monitoring result value. For example, the third device 300 may activate a bypass path to the equalization circuit 210 by turning on the bypass switch 231. The bypass control signal BCC may be a signal provided to the second device 200 through the third device 300 according to a user's operation.

Referring to FIG. 5A, the bypass control circuit 232 may turn off the bypass switch 231 when the noise monitoring result value is greater than the bypass reference value. In one or more examples, in some embodiments, the bypass control circuit 232 may turn on the bypass switch 231 based on the bypass control signal BCC that instructs the bypass control circuit 232 to turn on the bypass switch 231. For example, the signal provided to the second device 200 may be equalized.

In one or more embodiments, when the bypass switch 231 is turned off, a signal provided from the first device 100 to the second device 200 through the first channel CH1 may be provided to the third device 300 through the second channel CH2 along a first path PATH1 defined by the first node N1, the third node N3, and the second node N2.

In one or more embodiments, when the bypass switch 231 is turned off, a signal provided from the third device 300 to the second device 200 through the second channel CH2 may be provided to the first device 100 through the first channel CH1 along the first path PATH1.

Referring to FIG. 5B, the bypass control circuit 232 may turn on the bypass switch 231 when the noise monitoring result value is less than the bypass reference value. In one or more examples, in some embodiments, the bypass control circuit 232 may turn on the bypass switch 231 based on a bypass control signal BCC that instructs the bypass control circuit 232 to turn on the bypass switch 231. For example, the signal provided to the second device 200 may not be equalized. When the bypass switch 231 is turned on, the signal does not pass through the equalization circuit 210 and thus, an equalization operation may not be performed on the signal, and accordingly, the amount of power required to transmit the signal may be reduced.

In one or more embodiments, when the bypass switch 231 is turned on, a signal provided by the first device 100 to the second device 200 through the first channel CH1 may be provided to the third device 300 through the second channel CH2 along a second path PATH2 defined by the first node N1, the bypass switch 231, and the second node N2.

In one or more embodiments, when the bypass switch 231 is turned on, a signal provided by the third device 300 to the second device 200 through the second channel CH2 may be provided to the first device 100 through the first channel CH1 along the second path PATH2.

Referring to FIG. 5c, the form of a signal monitored by the bypass control circuit 232 may be an eye diagram form, such as the waveform illustrated in FIG. 5C. As understood by one of ordinary skill in the art, an eye diagram may be a representation digital signal that provides an evaluation tool for intersymbol interference. For example, a high amount of intersymbol interference results in a closure of the eye diagram and vice versa, a low amount of intersymbol interference results in an opening of the eye diagram. The bypass control circuit 232 may monitor signals provided to the second device 200 through the EOM circuit 233.

In one or more embodiments, the bypass control circuit 232 may detect jitter and noise, etc. of a signal provided to the second device 200 through the first channel CH1 and a signal provided to the second device 200 through the second channel CH2, based on information obtained through an eye diagram, and may generate a noise monitoring result value based on a detected value. The information that the bypass control circuit 232 may obtain through the eye diagram may include an eye height EH and an eye length EL.

In one or more embodiments, the noise monitoring result value may correspond to the size of the jitter or noise occurring in the process of transmitting a signal to the second device 200 through the first channel CH1 and the second channel CH2

In one or more embodiments, the noise monitoring result value may be inversely proportional to the eye height EH and the eye length EL. For example, when the noise of the signal is small, the eye height EH may be large. When the noise of the signal is large, the eye height EH may be small.

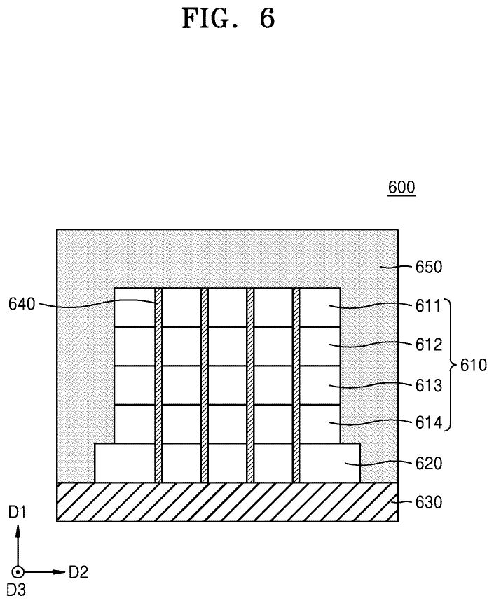

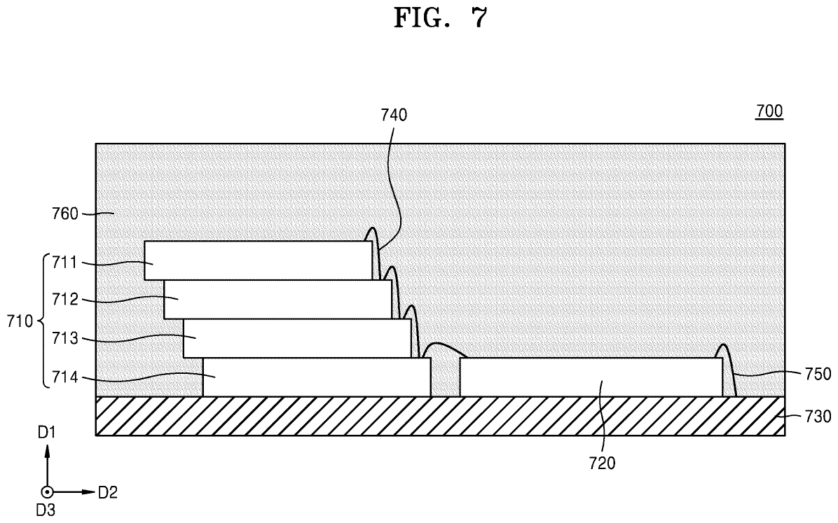

FIGS. 6 and 7 are diagrams illustrating a semiconductor package according to one or more embodiments. FIGS. 6 and 7 may be described with reference to FIG. 1, and duplicate descriptions thereof may be omitted.

In the present specification, unless specifically defined, a direction perpendicular to a substrate 630 may be referred to as a first direction D1. A second direction D2 may be a direction perpendicular to the first direction D1, and a third direction D3 may be a direction perpendicular to the first direction D1 and the second direction D2.

Referring to FIG. 6, a semiconductor package 600 may include a first device 610, a second device 620, the substrate 630, a plurality of through vias 640, and a molding layer 650.

The first device 610 may correspond to the first device 100 of FIG. 1, and the second device 620 may correspond to the second device 200 of FIG. 1. The second device 620 may be placed on the substrate 630. The first device 610 may be placed on the second device 620. In some embodiments, the third device 300 of FIG. 1 may be referred to as an external device.

The first device 610 may include first to fourth memory chips 611 to 614. The first to fourth memory chips 611 to 614 may be stacked in a vertical direction (i.e., the first direction D1). In FIG. 6, four memory chips are illustrated as an example, and it may be understood that a smaller or larger number of memory chips may be included in the first device 610.

The plurality of through vias 640 may electrically connect the first device 610 and the second device 620 to the substrate 630 by passing through the first to fourth memory chips 611 to 614 of the first device 610 and the second device 620.

In some embodiments, the substrate 630 may include a semiconductor material, such as silicon (Si). In one or more examples, the substrate 630 may include a semiconductor material, such as germanium (Ge).

The molding layer 650 may surround the first device 610 and the second device 620. In some embodiments, the molding layer 650 may include an epoxy resin or a polyimide resin. The molding layer 650 may include, for example, an epoxy molding compound (EMC).

Referring to FIG. 7, a semiconductor package 700 may include a first device 710, a second device 720, a substrate 730, a plurality of wires 740, and a molding layer 650.

The first device 710 may correspond to the first device 100 of FIG. 1, and the second device 720 may correspond to the second device 200 of FIG. 1. The first device 710 and the second device 720 may be arranged on the substrate 730. The first device 710 and the second device 720 may be arranged to be spaced apart from each other in a horizontal direction (e.g., the second direction D2). In some embodiments, the third device 300 of FIG. 1 may be referred to as an external device.

The first device 710 may include first to fourth memory chips 711 to 714. The first to fourth memory chips 711 to 714 may be stacked in a step shape, as illustrated in FIG. 7. In FIG. 7, four memory chips are illustrated as an example, and it may be understood that a smaller or larger number of memory chips may be included in the first device 710.

The first to fourth memory chips 711 to 714 may be electrically connected to the second device 720 through the plurality of wires 740. The second device 720 may be electrically connected to the substrate 730 through a wire 750.

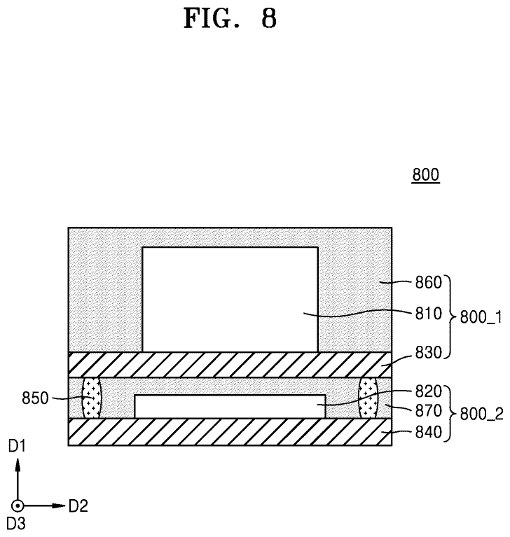

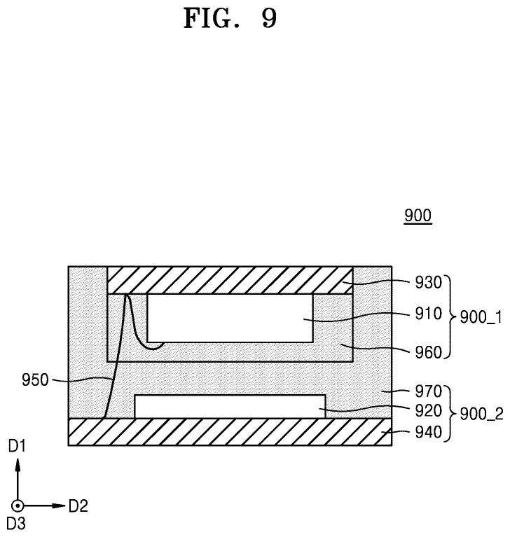

FIGS. 8 and 9 are diagrams illustrating a semiconductor package according to one or more embodiments. FIGS. 8 and 9 may be described with reference to FIG. 1, and duplicate descriptions thereof may be omitted.

Referring to FIG. 8, a semiconductor package 800 may include a first package 800_1 and a second package 800_2.

The first package 800_1 may include a first device 810, a first substrate 830, and a molding layer 860.

The first device 810 may correspond to the first device 100 of FIG. 1. The first device 810 may be placed on the first substrate 830 and may be electrically connected to the first substrate 830. The molding layer 860 may surround the first device 810.

The second package 800_2 may include a second device 820, a second substrate 840, a connection terminal 850, and a molding layer 870.

The second device 820 may correspond to the second device 200 of FIG. 1. The second device 820 may be placed on the second substrate 840 and may be electrically connected to the second substrate 840. The connection terminal 850 may electrically connect the first substrate 830 and the second substrate 840. The connection terminal 850 may be, for example, a solder ball or a solder bump. In FIG. 8, the molding layer 870 is illustrated to surround the second device 820 and the connection terminal 850, but this is an example and the molding layer 870 may surround only the second device 820.

The first package 800_1 may be placed on the second package 800_2. The semiconductor package 800 may be a semiconductor package packaged in a Package on Package (PoP) manner.

Referring to FIG. 9, a semiconductor package 900 may include a first package 900_1 and a second package 900_2.

The first package 900_1 may include a first device 910, a first substrate 930, and a molding layer 960.

The first device 910 may correspond to the first device 100 of FIG. 1. The first device 910 may be placed below the first substrate 930 in a first direction D1. The molding layer 960 may surround the first device 910.

The first device 910 may be placed on the first substrate 930 and may be electrically connected to the first substrate 930. The molding layer 960 may surround the first device 910. The first substrate 930 may be attached to the upper surface of the semiconductor package 900.

The first device 910 may be electrically connected to the first substrate 930 via a wire 950. The first substrate 930 may be electrically connected to a second substrate 940 via the wire 950.

The second package 900_2 may include a second device 920, the second substrate 940, and a molding layer 970.

The second device 920 may be placed on the second substrate 940 and may be electrically connected to the second substrate 940. The molding layer 970 may surround the second device 920 and the first package 900_1.

The first package 900_1 may be placed spaced apart from the second package 900_2 in the first direction D1. In one or more embodiments, the first package 900_1 may be included in the semiconductor package 900 in an inverted state, as illustrated in FIG. 9, and the semiconductor package 900 may be a semiconductor package packaged in a Package in Package (PiP) manner.

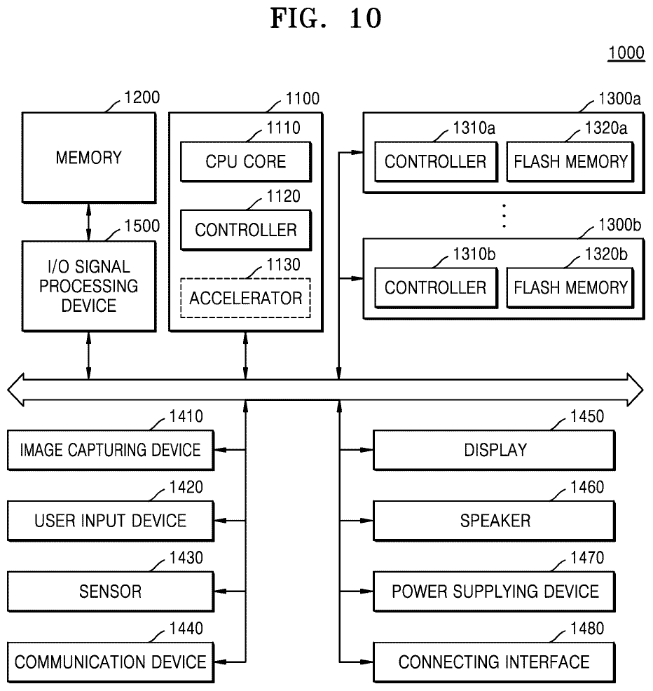

FIG. 10 is a block diagram of a system 1000 according to one or more embodiments.

Referring to FIG. 10, the system 1000 may include the memory system 10 described with reference to FIGS. 1 to 9. The system 1000 may be a mobile system, such as a mobile phone, a smart phone, a tablet personal computer (PC), a wearable device, a healthcare device, or an Internet of Things (IOT) device. However, the system 1000 of FIG. 10 is not necessarily limited to a mobile system and may be a personal computer, a laptop computer, a server, a media player, or an automotive device, such as a navigation device.

Referring to FIG. 10, the system 1000 may include a main processor 1100, a memory 1200, and storage devices 1300a and 1300b, and may additionally include one or more of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000, more specifically, the operations of other components forming the system 1000. The main processor 1100 may be implemented as a general-purpose processor, a dedicated processor, an application processor, or the like.

The main processor 1100 may include one or more CPU cores 1110, and may further include a controller 1120 for controlling the memory 1200 and/or the storage devices 1300a and 1300b. According to one or more embodiments, the main processor 1100 may further include an accelerator block 1130, which is a dedicated circuit for high-speed data operations, such as artificial intelligence (AI) data operations. The accelerator block 1130 may include a Graphics Processing Unit (GPU), a Neural Processing Unit (NPU), and/or a Data Processing Unit (DPU), and may be implemented as a separate chip physically independent from other components of the main processor 1100.

The memory 1200 may be used as a main memory device of the system 1000 and may include volatile memory, such as SRAM and/or DRAM, but may also include non-volatile memory, such as flash memory, PRAM, and/or RRAM. The memory 1200 may also be implemented in the same package as the main processor 1100.

The memory 1200 may include a plurality of memory chips. The memory 1200 may communicate with the main processor 1100 through an input/output signal processing device 1500. The input/output signal processing device 1500 may correspond to the second device 200 described with reference to FIGS. 1 to 9.

Each of the storage devices 1300a and 1300b may function as a non-volatile storage device that stores data regardless of whether power is supplied, and may have a relatively large storage capacity compared to the memory 1200. The storage devices 1300a and 1300b may respectively include storage controllers 1310a and 1310b, and non-volatile memory (NVM) storages 1320a and 1320b that stores data under the control of the storage controllers 1310a and 1310b. The non-volatile storages 1320a and 1320b may each include V-NAND flash memory of a 2-dimensional (2D) structure or a 3-dimensional (3D) structure, but may also include other types of non-volatile memory, such as PRAM and/or RRAM.

The storage devices 1300a and 1300b may be included in the system 1000 while being physically separated from the main processor 1100, or may be implemented in the same package as the main processor 1100. In addition, the storage devices 1300a and 1300b may each have a form such as a memory card, and may be detachably coupled with other components of the system 1000 through an interface, such as the connecting interface 1480 described below. The storage devices 1300a and 1300b may be devices to which standard specifications, such as universal flash storage (UFS), are applied, but are not necessarily limited thereto.

The image capturing device 1410 may be capable of photographing still images or moving images, and may be a camera, a camcorder, and/or a webcam.

The user input device 1420 may receive various types of data input from a user of the system 1000, and may be a touch pad, a keypad, a keyboard, a mouse, and/or a microphone.

The sensor 1430 may detect various types of physical quantities that may be obtained from the outside of the system 1000, and may convert the detected physical quantities into electrical signals. The sensor 1430 may be a temperature sensor, a pressure sensor, an illuminance sensor, a position sensor, an acceleration sensor, a biosensor, and/or a gyroscope.

The communication device 1440 may transmit and receive signals between the communication device 1440 and other devices outside the system 1000 according to various communication protocols. The communication device 1440 may include an antenna, a transceiver, and/or a modem.

The display 1450 and thee speaker 1460 may function as output devices that output visual information and auditory information to the user of the system 1000, respectively.

The power supplying device 1470 may appropriately convert power supplied from a battery (not shown) built into the system 1000 and/or an external power source and supply the converted power to each component of the system 1000.

The connecting interface 1480 may provide a connection between the system 1000 and an external device that is connected to the system 1000 and may exchange data with the system 1000. The connecting interface 1480 may be implemented in various interface methods, such as an Advanced Technology Attachment (ATA), a Serial ATA (SATA), an external SATA (e-SATA), a Small Computer Small Interface (SCSI), a Serial Attached SCSI (SAS), a Peripheral Component Interconnection (PCI), a PCI express (PCIe), an NVM express (NVMe), an IEEE 1394, a Universal Serial Bus (USB), a Secure Digital (SD) card, a Multi-Media Card (MMC), an embedded Multi-Media Card (eMMC), a Universal Flash Storage (UFS), an embedded Universal Flash Storage (eUFS), and a Compact Flash (CF) card interface.

While the embodiments have been particularly shown and described with reference to embodiments thereof, it will be understood that various changes in form and details may be made therein without departing from the spirit and scope of the following claims.

What is claimed is:

1. A semiconductor package comprising:
a substrate;
a first device comprising a plurality of memory chips; and
a second device configured to:
receive a first signal from the first device through a first channel;
transmit the first signal to an external device through a second channel;
receive a second signal from the external device through the second channel; and
transmit the second signal to the first device through the first channel,
wherein the first channel connects the first device to the second device, and the second channel connects the external device to the second device,
wherein the second device comprises:
an equalization circuit connected to the first channel and the second channel, the equalization circuit configured to equalize the first signal received from the first device and the second signal received from the external device;
a termination circuit configured to control an electrical connection state of a plurality of termination resistor circuits based on a termination request received from the first device and the external device; and
a bypass circuit comprising a bypass switch connected in parallel with the equalization circuit, the bypass circuit configured to control the bypass switch based on noise of the first signal received through the first channel and noise of the second signal received through the second channel.

2. The semiconductor package of claim 1, wherein the equalization circuit comprises a transmitter and a receiver,
wherein the receiver is configured to equalize the first signal received from the first device through the first channel and provide the first signal equalized by the receiver to the transmitter, and
the transmitter is configured to equalize the first signal equalized by the receiver and provide the first signal equalized by the transmitter to the external device through the second channel.

3. The semiconductor package of claim 2, wherein the transmitter comprises a feed forward equalizer, and
the receiver comprises:
a continuous time linear equalizer; and
a decision feedback equalizer.

4. The semiconductor package of claim 1, wherein the termination circuit comprises:
a first termination resistor circuit of the plurality of termination resistor circuits, the first termination resistor circuit connected to the first channel and comprising a first pull-up resistor and a first pull-down resistor;
a second termination resistor circuit of the plurality of termination resistor circuits, the second termination resistor circuit connected to the second channel and comprising a second pull-up resistor and a second pull-down resistor; and
a termination control circuit configured to control an electrical connection state of the first pull-up resistor and the first pull-down resistor of the first termination resistor circuit and the second pull-up resistor and the second pull-down resistor of the second termination resistor circuit.

5. The semiconductor package of claim 4, wherein the termination control circuit is further configured to:
turn off at least one of the first pull-up resistor and the first pull-down resistor of the first termination resistor circuit based on a first termination request received from the first device, and
turn off at least one of the second pull-up resistor and the second pull-down resistor of the second termination resistor circuit based on a second termination request received from the external device.

6. The semiconductor package of claim 1, wherein the bypass circuit further comprises a bypass control circuit configured to change an electrical connection state of the bypass switch based on a noise monitoring result value corresponding to noise of the first signal received through the first channel and the noise of the second signal received through the second channel, and
wherein first end of the bypass switch is connected to the first channel, and a second end of the bypass switch is connected to the second channel.

7. The semiconductor package of claim 6, wherein the bypass control circuit comprises an Eye Opening Monitoring (EOM) circuit.

8. The semiconductor package of claim 6, wherein the bypass control circuit is further configured to:
turn on the bypass switch based on the noise monitoring result value being less than a bypass reference value, and
turn off the bypass switch based on the noise monitoring result value being greater than the bypass reference value.

9. The semiconductor package of claim 1, wherein the second device is on the substrate, the first device is on the second device, and the plurality of memory chips are stacked in a first direction and electrically connected to the second device through a plurality of through vias.

10. The semiconductor package of claim 1, wherein the first device and the second device are each on the substrate, the first device and the second device are arranged spaced apart from each other in a first direction, and the plurality of memory chips are stacked in a second direction perpendicular to the first direction and electrically connected to the second device through a wire.

11. A semiconductor package comprising:
a first package comprising a first substrate, and a first device comprising a plurality of memory chips, connected to the first substrate; and
a second package comprising a second substrate connected to the first substrate, and a second device configured to provide a first signal received from the first device through a first channel to an external device through a second channel, and to provide a second signal received from the external device through the second channel to the first device through the first channel, the second device being connected to the second substrate,
wherein the first channel connects the first device to the second device, and the second channel connects the external device to the second device,
wherein the second device comprises:
an equalization circuit connected to the first channel and the second channel, the equalization circuit configured to equalize the first signal received from the first device and the second signal received from the external device;
a termination circuit configured to control an electrical connection state of a plurality of termination resistor circuits based on a termination request received from the first device and the external device; and
a bypass circuit comprising a bypass switch connected in parallel with the equalization circuit, the bypass circuit configured to control the bypass switch based on noise of the first signal received through the first channel and noise of the second signal received through the second channel.

12. The semiconductor package of claim 11, wherein the first package is located on the second package.

13. The semiconductor package of claim 11, wherein the equalization circuit comprises a transmitter and a receiver,
wherein the receiver is configured to equalize the first signal received from the first device through the first channel and provide the first signal equalized by the receiver to the transmitter, and
the transmitter is configured to equalize the first signal equalized by the receiver and provide the first signal equalized by the transmitter to the external device through the second channel.

14. The semiconductor package of claim 11, wherein the termination circuit comprises:
a first termination resistor circuit from the plurality of termination resistor circuits connected to the first channel and comprising a first pull-up resistor and a first pull-down resistor;
a second termination resistor circuit from the plurality of termination resistor circuits connected to the second channel and comprising a second pull-up resistor and a second pull-down resistor; and
a termination control circuit configured to control an electrical connection state of the first pull-up resistor and the first pull-down resistor of the first termination resistor circuit and the second pull-up resistor and the second pull-down resistor of the second termination resistor circuit.

15. The semiconductor package of claim 14, wherein the termination control circuit is further configured to:
turn off at least one of the first pull-up resistor and the first pull-down resistor of the first termination resistor circuit based on a first termination request received from the first device, and
turn off at least one of the second pull-up resistor and the second pull-down resistor of the second termination resistor circuit based on a second termination request received from the external device.

16. The semiconductor package of claim 11, wherein the bypass circuit further comprises a bypass control circuit configured to change an electrical connection state of the bypass switch based on a noise monitoring result value corresponding to noise of the first signal received through the first channel and the noise of the second signal received through the second channel, and
wherein a first end of the bypass switch is connected to the first channel, and a second end of the bypass switch is connected to the second channel.

17. The semiconductor package of claim 16, wherein the bypass control circuit is further configured to:
turn on the bypass switch based on the noise monitoring result value being less than a bypass reference value, and
turn off the bypass switch based on the noise monitoring result value being greater than the bypass reference value.

18. A memory system comprising:
an input/output signal processing device connected to a first channel and a second channel;
a memory device including a plurality of memory chips and connected to the input/output signal processing device through the first channel; and
a memory controller connected to the input/output signal processing device through the second channel,
wherein the input/output signal processing device is configured to provide a first signal received from the memory device through the first channel to the memory controller through the second channel, and provide a second signal received from the memory controller through the second channel to the memory device through the first channel, and
wherein the input/output signal processing device comprises:
an equalization circuit configured to equalize the first signal received from the memory device and the second signal received from the memory controller;
a termination circuit configured to control an electrical connection state of a plurality of termination resistor circuits based on a termination request received from the memory device and the memory controller; and
a bypass circuit configured to control a bypass switch connected in parallel with the equalization circuit based on noise of the first signal received through the first channel and noise of the second signal received through the second channel.

19. The memory system of claim 18, wherein the termination circuit comprises:
a first termination resistor circuit from the plurality of termination resistor circuits connected to the first channel and comprising a first pull-up resistor and a first pull-down resistor;
a second termination resistor circuit from the plurality of termination resistor circuits connected to the second channel and comprising a second pull-up resistor and a second pull-down resistor; and
a termination control circuit configured to control an electrical connection state of the first pull-up resistor and the first pull-down resistor of the first termination resistor circuit and the second pull-up resistor and the second pull-down resistor of the second termination resistor circuit.

20. The memory system of claim 18, wherein the bypass circuit further comprises a bypass control circuit configured to change an electrical connection state of the bypass switch based on a noise monitoring result value corresponding to noise of the first signal received through the first channel and the noise of the second signal received through the second channel, and
wherein a first end of the bypass switch is connected to the first channel, and a second end of the bypass switch is connected to the second channel.
